(19) United States
(12) Patent Application Publication
(10) Pub. No.: US 2011/0304056 A1
(43) Pub. Date: Dec. 15, 2011

(54) STACK-TYPE SEMICONDUCTOR PACKAGE AND METHOD OF MANUFACTURING THE SAME

(75) Inventors: Dong-hun Lee, Seoul (KR); Hyung-gil Baek, Suwon-si (KR); Kun-dae Yeom, Cheonan-si (KR)

(73) Assignee: SAMSUNG ELECTRONICS CO., LTD., Suwon-si (KR)

(21) Appl. No.: 13/158,722

(22) Filed: Jun. 13, 2011

(30) Foreign Application Priority Data
Jun. 14, 2010 (KR) 10-2010-0056189

(51) Int. Cl. H01L 23/48

(52) U.S. Cl. 257/774; 257/E23.011

(57) ABSTRACT

A stack-type semiconductor package includes: a substrate; a first through electrode module stacked on the substrate comprising a first chip and a second chip connected to the first chip by a first through electrode; a second through electrode module stacked on the first through electrode comprising a third chip and a fourth chip connected to the third chip by a second through electrode; and a signal transmission medium for electrically connecting the substrate to the first through electrode module and the second through electrode module. The stack-type semiconductor package may be highly integrated, reliability thereof is improved by increasing strength of the chips, stacking in high-steps is possible, the stack-type semiconductor package may be thin and simple, and productivity thereof may be significantly increased.

### CROSS-REFERENCE TO RELATED APPLICATION

This application claims the benefit under 35 U.S.C. 119 of Korean Patent Application No. 10-2010-0056189, filed in the Korean Intellectual Property Office on Jun. 14, 2010, the entire contents of which are incorporated herein by reference.

### BACKGROUND

The inventive concept relates to stack-type semiconductor packages and methods of manufacturing stack-type semiconductor packages.

In general, a semiconductor chip is formed on a wafer according to a process of manufacturing a semiconductor chip. The semiconductor chip is separated from the wafer according to a separation process. Then, a semiconductor package, which includes the semiconductor chip, is manufactured according to a packaging process.

In general, the semiconductor package includes a substrate, a chip stacked on the substrate, a sealing member for protecting the chip, and a signal transmission medium, such as a wire, that electrically connects the chip and the substrate to each other.

With the ever-increasing demand for high-speed and small-size devices, the semiconductor package requires high-speed and high integration packaging. Accordingly, a plurality of chips may be stacked upon each other in the semiconductor package, and multi-layers of semiconductor package devices may be stacked on a circuit board.

In addition, in response to the demand for smaller, thinner and simpler electronic products, the thickness of stacking chips is decreased, the number of stacking chips is increased, and thicknesses of a sealing member and a package are reduced.

### SUMMARY

The inventive concept provides a stack-type semiconductor package. More specifically, the inventive concept provides a stack-type semiconductor package having improved integration, having improved productivity by reducing stress occurring due to an external force exerted on a chip, and having high quality by increasing durability.

According to one aspect, the inventive concept is directed to a stack-type semiconductor package. The package includes a substrate and a first through electrode module stacked on the substrate, the first through electrode module comprising a first chip and a second chip connected to the first chip by a first through electrode. The package also includes a second through electrode module stacked on the first through electrode module, the second through electrode module comprising a third chip and a fourth chip connected to the third chip by a second through electrode. The package further includes a signal transmission medium for electrically connecting the substrate to the first through electrode module and the second through electrode module.

In some embodiments, the signal transmission medium comprises wires that connect the substrate to the first through electrode module and the second through electrode module.

In some embodiments, the first through electrode module comprises the first chip and the second chip, each of the first chip and the second chip including an active layer and a non-active layer. The first through electrode is formed by penetrating the active layer and non-active layer of the first chip and the active layer of the second chip. A thickness of the non-active layer of the second chip is larger than a thickness of the non-active layer of the first chip, such that strength of the first through electrode module is reinforced.

In some embodiments, the first through electrode module further comprises a fifth chip connected to the first chip and the second chip through a fifth through electrode.

In some embodiments, the first through electrode module and the second through electrode module are stacked in the form of steps inclined in one direction, the first through electrode module being connected to the second through electrode module through the signal transmission medium such that one of a plurality of ends of the first through electrode and the second through electrode is exposed.

In some embodiments, the package further comprises: a third through electrode module stacked on the second through electrode module, the third through electrode module comprising a sixth chip and a seventh chip connected to the sixth chip by a third through electrode; a fourth through electrode module stacked on the third through electrode module, the fourth through electrode module comprising an eighth chip and a ninth chip connected to the eighth chip by a fourth through electrode; and a signal transmission medium for electrically connecting the substrate to the third through electrode module and the fourth through electrode module.

In some embodiments, the first through electrode module and the second through electrode module are stacked in the form of steps inclined in one direction, and the third through electrode module and the fourth through electrode module are stacked in the form of steps inclined in another direction different from the one direction, the signal transmission medium being connected to one of the exposed ends of the first through electrode, the second through electrode, the third through electrode, and the fourth through electrode.

In some embodiments, when the first through electrode module and the second through electrode module are connected by the signal transmission media, a spacer is interposed between the first through electrode module and the second through electrode module, such that first ends of the first through electrode and the second through electrode are exposed.

In some embodiments, the substrate comprises: a substrate core; a pattern layer electrically connected to the signal transmission medium; and a protective layer covering and protecting a part of the pattern layer and the substrate core.

In some embodiments, the package further comprises a sealing member for covering and protecting the first through electrode module, the second through electrode module, and the signal transmission medium.

According to another aspect, the inventive concept is directed to a stack-type semiconductor package comprising a substrate and a first through electrode module stacked on the substrate. The first through electrode module comprises a first chip and a second chip connected to the first chip by a first through electrode. Each of the first chip and the second chip includes an active layer and a non-active layer. The first through electrode is formed by penetrating the active layer and non-active layer of the first chip and the active layer of the second chip. A thickness of the non-active layer of the second chip is larger than a thickness of the non-active layer of the first chip, such that strength of the first through electrode module is reinforced. A second through electrode module is stacked on the first through electrode module. The second through electrode module comprises a third chip and a fourth chip connected to the third chip by a second through electrode. A signal transmission medium electrically connects the substrate to the first through electrode module and the second through electrode module. The substrate comprises: a substrate core; a pattern layer electrically connected to the signal transmission medium; and a protective layer covering and protecting a part of the pattern layer and the substrate core.

In some embodiments, the signal transmission medium comprises at least one wire that connects the substrate to at least one of the first through electrode module and the second through electrode module.

In some embodiments, the first through electrode module and the second through electrode module are stacked in an inclined step configuration.

In some embodiments, the package further comprises a third through electrode module stacked on the second through electrode module and a fourth through electrode module stacked on the third through electrode module.

In some embodiments, the first through electrode module and the second through electrode module are stacked in a first inclined step configuration in a first direction, and the third through electrode module and the fourth through electrode module are stacked in a second inclined step configuration in a second direction different from the first direction.

In some embodiments, the package further comprises a sealing member for covering and protecting the first through electrode module, the second through electrode module, and the signal transmission medium.

### BRIEF DESCRIPTION OF THE DRAWINGS

The foregoing and other features and advantages of the inventive concept will be apparent from the more particular description of preferred aspects of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 is a schematic cross-sectional view of a stack-type semiconductor package according to an embodiment of the inventive concept.

FIG. 2 is a schematic plan view of the stack-type semiconductor package of FIG. 1.

FIG. 3 is a schematic expanded cross-sectional view of a first through electrode module of FIG. 1, according to an embodiment of the inventive concept.

FIG. 4 is a schematic expanded cross-sectional view of a first through electrode module of FIG. 3, according to another embodiment of the inventive concept.

FIG. 5 is a schematic cross-sectional view of a stack-type semiconductor package according to another embodiment of the inventive concept.

FIG. 6 is a schematic cross-sectional view of a stack-type semiconductor package according to another embodiment of the inventive concept.

FIG. 7 is a schematic cross-sectional view of a stack-type semiconductor package according to another embodiment of the inventive concept.

### DETAILED DESCRIPTION OF THE EMBODIMENTS

Hereinafter, stack-type semiconductor packages according to one or more embodiments of the inventive concept will be described more fully with reference to the accompanying drawings. The inventive concept may be embodied in many different forms and should not be construed as being limited to the embodiments set forth herein.

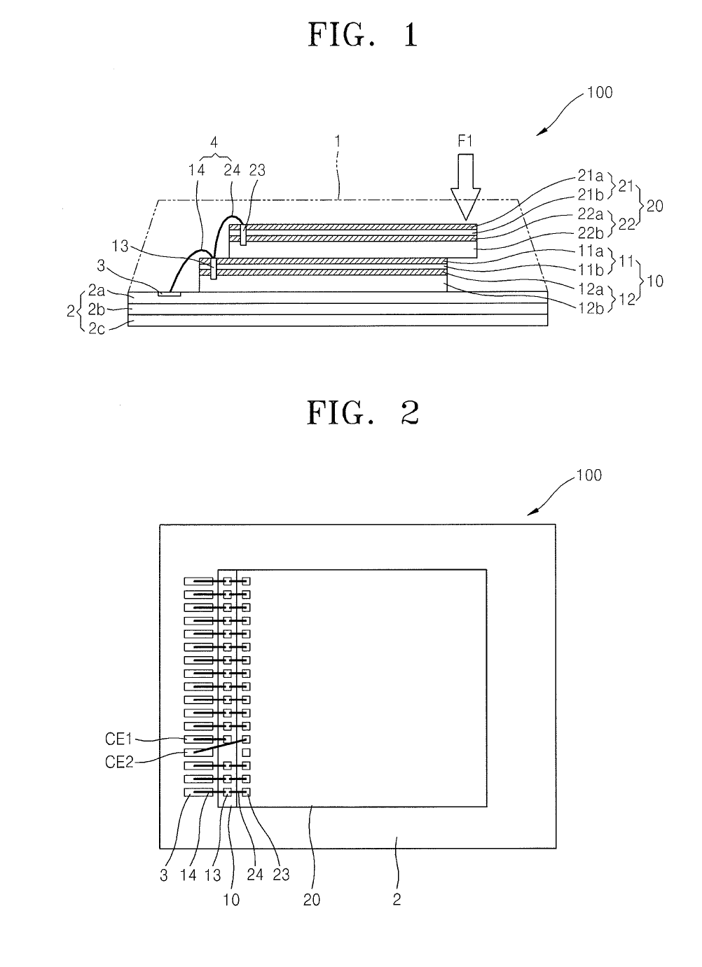

FIG. 1 is a schematic cross-sectional view of a stack-type semiconductor package 100 according to an exemplary embodiment of the inventive concept. FIG. 2 is a schematic plan view of the stack-type semiconductor package 100 of FIG. 1.

Referring to FIGS. 1 and 2, the stack-type semiconductor package 100 according to some embodiments of the inventive concept includes a sealing member 1, a substrate 2, a first through electrode module 10, a second through electrode module 20, and a signal transmission medium 4. The sealing member 1 covers and protects the first through electrode module 10, the second through electrode module 20, and the signal transmission medium 4. The sealing member 1 may include various resins formed of an insulating material.

The substrate 2 provides a base for and supports the first through electrode module 10 and the second through electrode module 20. The substrate includes conductors, such as printed circuit conductive elements or traces, such that the substrate electrically connects the first through electrode module 10 and the second through electrode module 20 to the exterior of the device 100. Therefore, input and output signals of the first through electrode module 10 and the second through electrode module 20 may be input and output to the exterior of the device 100. The substrate 2 may further include a solder ball, a bump, or a lead frame to electrically connect the device 100 to external devices.

The substrate 2 may include a substrate core 2b. The substrate 2 also includes an upper protective layer 2a and a lower protective layer 2c. A pattern layer 3 is formed on one side of the upper protective layer 2a. The pattern layer 3 can include the conductive elements or traces which electrically connect to the signal transmission medium 4. The upper and lower protective layers 2a and 2c, respectively, cover and protect a part of the pattern layer 3 and the substrate core 2b.

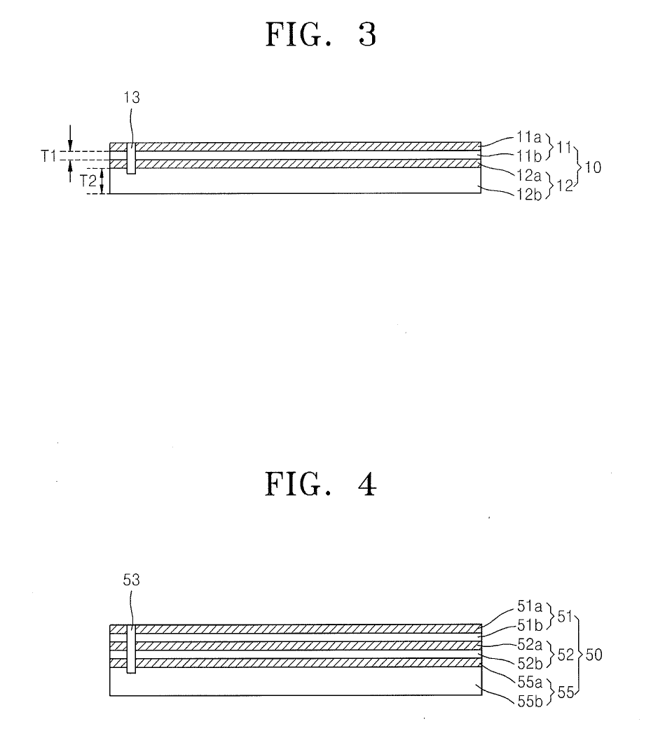

FIG. 3 is a schematic expanded cross-sectional view of the first through electrode module 10 of FIG. 1, according to an embodiment of the inventive concept. Referring to FIGS. 1 and 3, the stack-type semiconductor package 100 is formed by modulating at least two first and second chips 11 and 12 by a first through electrode 13. This reinforces strength for an external force F1. This includes the first through electrode module 10 and the second through electrode module 20. That is, as illustrated in FIGS. 1 and 3, in some exemplary embodiments, the first through electrode module 10 is stacked on the substrate 2 and includes the first chip 11 and the second chip 12 connected to the first chip 11 through the first through electrode 13.

As illustrated in FIG. 3, the first through electrode module 10 may include the first chip 11 and the second chip 12. The first chip 11 includes an active layer 11a and a non-active layer 11b. The second chip 12 includes an active layer 12a and a non-active layer 12b. The first through electrode 13 may be formed by penetrating the active layer 11a and the non-active layer 11b of the first chip 11 and the active layer 12a of the second chip 12.

As noted above, it is important that the through electrode modules be made thin Accordingly, as illustrated in FIG. 3, in some exemplary embodiments, in order to make the first through electrode module 10 thin, the non-active layer 11b of the first chip 11 is thinned by using back grinding. As a result, a total thickness of the first chip 11 is reduced.

On the other hand, in order to improve strength of the first through electrode module 10, the non-active layer 12b of the second chip 12 is not back ground for a relatively short period of time. As a result, a total thickness of second chip 12 may be increased. That is, as illustrated in FIG. 3, according to some exemplary embodiments, a thickness T2 of the non-active layer 12b of the second chip 12 may be greater than a thickness T1 of the non-active layer 11b of the first chip 11. This reinforces strength of the first through electrode module 10.

Therefore, in accordance with embodiments of the inventive concept, the degrees of thinning and strength reinforcement may be appropriately controlled by using a difference between the thicknesses T1 and T2. The design and process may be optimized to satisfy both high integration and reliability requirements.

According to one exemplary embodiment, in manufacturing of the first through electrode module 10, the non-active layer 11b of the first chip 11 is back ground to be as thin as possible. The non-active layer 12b of the second chip 12 is back ground to be as thick as possible. Then, the first chip 11 and the second chip 12 are adhered to each other using an adhesive material. Then, after the first chip 11 and the second chip 12 are adhered to each other, a via hole for a through electrode is formed on the first chip 11 and the second chip 12 by a process such as punching, laser perforation, etching or other such process. Next, a conductive material, such as copper, silver, gold, or aluminum, is filled in the via hole by sputtering, assembling, coating or other such process, thereby forming the first through electrode 13.

The first through electrode module 10 may be formed using various methods, according to embodiments of the inventive concept. A via hole for a through electrode is formed in each of the first chip 11 and the second chip 12 by punching, laser perforation, etching or other such process. A conductive material, such as copper, silver, gold, or aluminum, is filled in the via hole by plating, sputtering or other such method, thereby forming the first through electrode 13 on the first chip 11 and the second chip 12. Next, the first chip 11 and the second chip 12 are adhered to each other, and each first through electrode 13 of each of the first chip 11 and second chip 12 is connected to each other, thereby forming one first through electrode 13.

As illustrated in FIG. 1, according to some exemplary embodiments, the second through electrode module 20 is stacked on the first through electrode module 10 and includes a third chip 21 and a fourth chip 22 connected to the third chip 21 through a second through electrode 23. The second through electrode module 20 may be manufactured in the same manner as the first through electrode module 10. Accordingly, detailed description of manufacturing the second through electrode module 20 will not be repeated.

Accordingly, as illustrated in FIG. 1, the first through electrode module 10 and the second through electrode module 20 may be adhered to each other in a module structure by making pairs of the first, second, third, and fourth chips 11, 12, 21, and 22. As a result, the first through electrode module 10 and the second through electrode module 20 are firmly supported. As a result, the structure is provided with sufficient strength to resist the external force F1 generated from an overhang portion of the second through electrode module 20 stacked on the upper side of the first through electrode module 10.

As illustrated in FIG. 1, the signal transmission medium 4 electrically connects the substrate 2, via the pattern layer 3, to the first through electrode module 10 and the second through electrode module 20, respectively. In some embodiments, the transmission medium 4 includes wires 14 and 24 that connect the substrate 2 to the first through electrode 13 and the second through electrode 23, respectively.

Accordingly, as illustrated in FIG. 1, the first through electrode module 10 and the second through electrode module 20 may be stacked in the form of steps inclined in one direction. The wires 14 and 24 are connected to one of the ends of the first through electrode 13 and the second through electrode 23 exposed on the first through electrode module 10 and the second through electrode module 20, respectively.

Accordingly, as illustrated in FIG. 2, the wires 14 and 24 may electrically connect the pattern layer 3 of the substrate 2 to the first through electrode 13 of the first through electrode module 10 and the second through electrode 23 of the second through electrode module 20, respectively.

In addition, in some exemplary embodiments, the pattern layer 3 of the substrate 2 may include a chip selection line CE1, which selects the first and second chips 11 and 12. The pattern layer 3 may also include a chip selection line CE2, which selects the third and fourth chips 21 and 22.

Accordingly, when operated, the first and second chips 11 and 12 may be selected by a selection signal applied through the chip selection line CE1. Similarly, when operated, the third and fourth chips 21 and 22 may be selected by a selection signal applied through the chip selection line CE2.

FIG. 4 is a schematic expanded cross-sectional view of a first through electrode module 50, according to another embodiment of the inventive concept. Referring to FIG. 4, the first through electrode module 50, when compared to the through electrode modules described in detail above, includes a fifth chip 55 connected to a first chip 51 and a second chip 52 through a fifth through electrode 53. Thus, in this exemplary embodiment, one module may include three chips 51, 52, and 55.

Moreover, according to the inventive concept, one module may include N chips, by using at least one through electrode, without departing from the inventive concept.

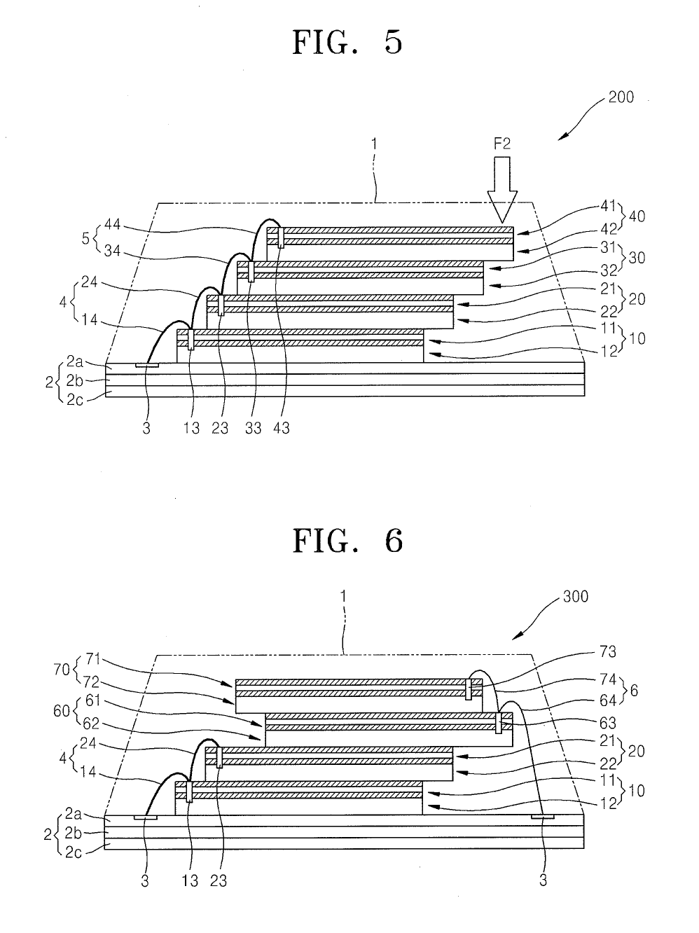

FIG. 5 is a schematic cross-sectional view of a stack-type semiconductor package 200 according to another embodiment of the inventive concept.

Referring to FIG. 5, the stack-type semiconductor package 200 according to the current embodiment of the inventive concept includes the substrate 2, the first through electrode module 10 described above in detail, the second through electrode module 20 described above in detail, a third through electrode module 30, a fourth through electrode module 40, and signal transmission media 4 and 5.

The first through electrode module 10 is stacked on the substrate 2. The first through electrode module 10 includes the first chip 11 and the second chip 12 connected to the first chip 11 through the first through electrode 13.

The second through electrode module 20 is stacked on the first through electrode module 10. The second through electrode module 20 includes the third chip 21 and the fourth chip 22 connected to the third chip 21 through the second through electrode 23.

The third through electrode module 30 is stacked on the second through electrode module 20. The third through electrode module 30 includes a sixth chip 31 and a seventh chip 32 connected to the sixth chip 31 through a third through electrode 33.

The fourth through electrode module 40 is stacked on the third through electrode module 30. The fourth through electrode module 40 includes an eighth chip 41 and a ninth chip 42 connected to the eighth chip 41 through a fourth through electrode 43.

The signal transmission medium 4 electrically connects the substrate 2 to the first through electrode module 10 and the second through electrode module 20. The signal transmission medium 4 may include the wires 14 and 24. The signal transmission medium 5 electrically connects the substrate 2 to the third through electrode module 30 and the fourth through electrode module 40. The signal transmission medium 5 may include wires 34 and 44.

As illustrated in FIG. 5, the first through electrode module 10, the second through electrode module 20, the third through electrode module 30, and the fourth through electrode module 40 may be stacked in the form of steps inclined in one direction. The wires 14, 24, 34, and 44 are connected to one of the exposed ends of the first through electrode 13, the second through electrode 23, the third through electrode 33, and the fourth through electrode 43, respectively.

Accordingly, sufficient strength to resist not only the external force F1 but also an external force F2 of FIG. 5 may be achieved in the stack-type semiconductor packages 100 and 200.

FIG. 6 is a schematic cross-sectional view of a stack-type semiconductor package 300 according to another embodiment of the inventive concept.

Referring to FIG. 6, in the stack-type semiconductor package 300 according to the current embodiment of the inventive concept, the first through electrode module 10 and the second through electrode module 20 may be stacked in the form of steps inclined in one direction. A third through electrode module 60 and a fourth through electrode module 70 may be stacked in the form of steps inclined in another direction. First ends of the first through electrode 13, the second through electrode 23, a third through electrode 63, and a fourth through electrode 73 are exposed. The first through electrode module 10 is connected to the second through electrode module 20, and the third through electrode module 60 is connected to the fourth through electrode module 70 using the signal transmission media 4 and 6, respectively.

According to some embodiments of the inventive concept, when the first through electrode module 10, the second through electrode module 20, the third through electrode module 60, and the fourth through electrode module 70 are stacked in the form of zigzag steps in multi-directions, as illustrated in FIG. 6, the first through electrode 13, the second through electrode 23, and the third through electrode 63 may be disposed to be adjacent to wires 14, 24, 64, and 74.

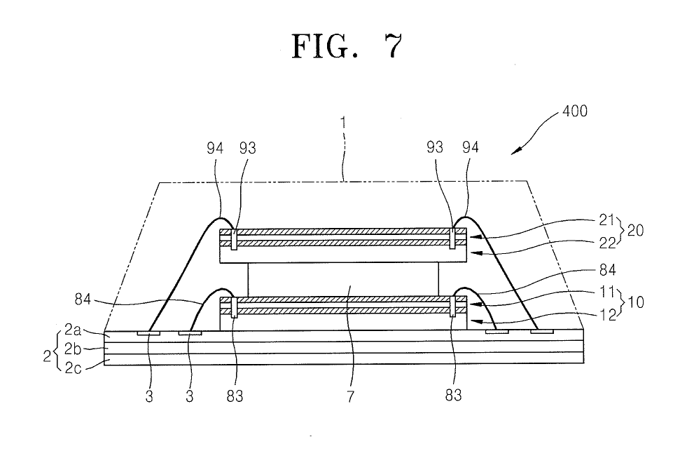

FIG. 7 is a schematic cross-sectional view of a stack-type semiconductor package 400 according to another embodiment of the inventive concept.

Referring to FIG. 7, in the stack-type semiconductor package 400 according to the current embodiment of the inventive concept, a spacer 7 may be interposed between the first through electrode module 10 and the second through electrode module 20. Exposed ends of a first through electrode 83 and a second through electrode 93 are connected using wires 84 and 94, respectively.

In the semiconductor package 400 shown in FIG. 7, a plurality of the first through electrodes 83 and the second through electrodes 93 may be disposed at both ends of the first, second, third, and fourth chips 11, 12, 21, and 22.

As described above, N modules may be stacked to constitute one package without departing from the technical concept of the inventive concept.

While the inventive concept has been particularly shown and described with reference to exemplary embodiments thereof, it will be understood that various changes in form and details may be made therein without departing from the spirit and scope of the inventive concept, which is defined by the following claims.

What is claimed is:

1. A stack-type semiconductor package comprising:
a substrate;
a first through electrode module stacked on the substrate, the first through electrode module comprising a first chip and a second chip connected to the first chip by a first through electrode;
a second through electrode module stacked on the first through electrode module, the second through electrode module comprising a third chip and a fourth chip connected to the third chip by a second through electrode; and
a signal transmission medium for electrically connecting the substrate to the first through electrode module and the second through electrode module.

2. The stack-type semiconductor package of claim 1, wherein the signal transmission medium comprises wires that connect the substrate to the first through electrode module and the second through electrode module.

3. The stack-type semiconductor package of claim 1, wherein:
the first through electrode module comprises the first chip and the second chip, each of the first chip and the second chip including an active layer and a non-active layer;
the first through electrode is formed by penetrating the active layer and non-active layer of the first chip and the active layer of the second chip; and
a thickness of the non-active layer of the second chip is larger than a thickness of the non-active layer of the first chip, such that strength of the first through electrode module is reinforced.

4. The stack-type semiconductor package of claim 1, wherein the first through electrode module further comprises a fifth chip connected to the first chip and the second chip through a fifth through electrode.

5. The stack-type semiconductor package of claim 1, wherein the first through electrode module and the second through electrode module are stacked in the form of steps inclined in one direction, the first through electrode module being connected to the second through electrode module through the signal transmission medium such that one of a plurality of ends of the first through electrode and the second through electrode is exposed.

6. The stack-type semiconductor package of claim 1, further comprising:
a third through electrode module stacked on the second through electrode module, the third through electrode module comprising a sixth chip and a seventh chip connected to the sixth chip by a third through electrode;
a fourth through electrode module stacked on the third through electrode module, the fourth through electrode module comprising an eighth chip and a ninth chip connected to the eighth chip by a fourth through electrode; and
a signal transmission medium for electrically connecting the substrate to the third through electrode module and the fourth through electrode module.

7. The stack-type semiconductor package of claim 6, wherein the first through electrode module and the second through electrode module are stacked in the form of steps inclined in one direction, and the third through electrode module and the fourth through electrode module are stacked in the form of steps inclined in another direction different from the one direction, the signal transmission medium being connected to one of the exposed ends of the first through electrode, the second through electrode, the third through electrode, and the fourth through electrode.

8. The stack-type semiconductor package of claim 1, wherein when the first through electrode module and the second through electrode module are connected by the signal transmission media, a spacer is interposed between the first through electrode module and the second through electrode module, such that first ends of the first through electrode and the second through electrode are exposed.

9. The stack-type semiconductor package of claim 1, wherein the substrate comprises:
a substrate core;
a pattern layer electrically connected to the signal transmission medium; and
a protective layer covering and protecting a part of the pattern layer and the substrate core.

10. The stack-type semiconductor package of claim 1, further comprising a sealing member for covering and protecting the first through electrode module, the second through electrode module, and the signal transmission medium.

11. A stack-type semiconductor package comprising:
a substrate;
a first through electrode module stacked on the substrate, the first through electrode module comprising a first chip and a second chip connected to the first chip by a first through electrode, each of the first chip and the second chip including an active layer and a non-active layer, the first through electrode being formed by penetrating the active layer and non-active layer of the first chip and the active layer of the second chip, a thickness of the non-active layer of the second chip being larger than a thickness of the non-active layer of the first chip, such that strength of the first through electrode module is reinforced;
a second through electrode module stacked on the first through electrode module, the second through electrode module comprising a third chip and a fourth chip connected to the third chip by a second through electrode; and
a signal transmission medium for electrically connecting the substrate to the first through electrode module and the second through electrode module; wherein the substrate comprises:
a substrate core;
a pattern layer electrically connected to the signal transmission medium; and
a protective layer covering and protecting a part of the pattern layer and the substrate core.

12. The stack-type semiconductor package of claim 11, wherein the signal transmission medium comprises at least one wire that connects the substrate to at least one of the first through electrode module and the second through electrode module.

13. The stack-type semiconductor package of claim 11, wherein the first through electrode module and the second through electrode module are stacked in an inclined step configuration.

14. The stack-type semiconductor package of claim 11, further comprising a third through electrode module stacked on the second through electrode module and a fourth through electrode module stacked on the third through electrode module.

15. The stack-type semiconductor package of claim 14, wherein:
the first through electrode module and the second through electrode module are stacked in a first inclined step configuration in a first direction; and
the third through electrode module and the fourth through electrode module are stacked in a second inclined step configuration in a second direction different from the first direction.

16. The stack-type semiconductor package of claim 11, further comprising a sealing member for covering and protecting the first through electrode module, the second through electrode module, and the signal transmission medium.
